(19) United States
(12) Patent Application Publication
(10) Pub. No.: US 2019/0214460 A1
(43) Pub. Date: Jul. 11, 2019

(54) FABRICATING NANOWIRE TRANSISTORS USING DIRECTIONAL SELECTIVE ETCHING

(71) Applicant: INTEL CORPORATION, Santa Clara, CA (US)

(72) Inventors: Nabil G. Mistkawi, Keizer, OR (US); Glenn A. Glass, Portland, OR (US)

(73) Assignee: INTEL CORPORATION, Santa Clara, CA (US)

(21) Appl. No.: 16/327,699

(22) PCT Filed: Sep. 30, 2016
(86) PCT No.: PCT/US2016/054730

§ 371 Date: Feb. 22, 2019

(51) Int. Cl. H01L 29/06; H01L 27/092; H01L 29/66; H01L 29/775

(52) U.S. Cl. CPC H01L 29/0673; H01L 27/0924; B82Y 10/00; H01L 29/66439; H01L 29/775; H01L 29/66545

(57) ABSTRACT

Techniques are disclosed for fabricating nanowire transistors using directional selective etching. Generally, a selective wet etch employing a given etchant can be used to remove at least one “select material” while not removing other material exposed to the etch (or removing that other material at a relatively slower rate). The techniques described herein expand upon such selective etch processing by including a directional component. A directional selective etch may include a selective etch that only (or primarily) removes the select material in a targeted direction and/or that discriminates against removal of material in a non-targeted direction. For instance, one or more SiGe nanowires can be formed from a stack of alternating sacrificial Si and non-sacrificial SiGe layers, where a directional selective etch removes the sacrificial Si layer(s) in a horizontal direction without adversely affecting exposed sub-channel/sub-fin Si (by using an etchant that discriminates against removing Si in a vertical direction).

### BACKGROUND

Semiconductor devices are electronic components that exploit the electronic properties of semiconductor materials, such as silicon (Si), germanium (Ge), and gallium arsenide (GaAs), to name a few examples. A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow from the source to the drain. In instances where the charge carriers are electrons, the FET is referred to as an n-channel device, and in instances where the charge carriers are holes, the FET is referred to as a p-channel device. Some FETs have a fourth terminal called the body or substrate, which can be used to bias the transistor. A metal-oxide-semiconductor FET (MOSFET) is configured with an insulator between the gate and the body of the transistor, and MOSFETs are commonly used for amplifying or switching electronic signals. In some cases, MOSFETs include side-wall or so-called gate spacers on either side of the gate that can help determine the channel length and can help with replacement gate processes, for example. Complementary MOS (CMOS) structures typically use a combination of p-channel MOSFETs (p-MOS) and n-channel MOSFETs (n-MOS) to implement logic gates and other digital circuits.

A FinFET is a MOSFET transistor built around a thin strip of semiconductor material (generally referred to as a fin). The conductive channel of the FinFET device resides on the outer portions of the fin adjacent to the gate dielectric. Specifically, current runs along/within both sidewalls of the fin (sides perpendicular to the substrate surface) as well as along the top of the fin (side parallel to the substrate surface). Because the conductive channel of such configurations essentially resides along the three different outer, planar regions of the fin, such a FinFET design is sometimes referred to as a tri-gate transistor. Other types of FinFET configurations are also available, such as so-called double-gate FinFETs, in which the conductive channel principally resides only along the two sidewalls of the fin (and not along the top of the fin). A nanowire transistor (sometimes referred to as a gate-all-around (GAA) or nanoribbon transistor) is configured similarly to a fin-based transistor, but instead of a finned channel region where the gate is on three portions (and thus, there are three effective gates), one or more nanowires are used for the channel region and the gate material generally surrounds each nanowire.

### BRIEF DESCRIPTION OF THE DRAWINGS

FIGS. 1A-L illustrate example integrated circuit (IC) structures resulting from a method configured to fabricate nanowire transistors using directional selective etching, in accordance with some embodiments of the present disclosure.

FIGS. 1H′ and 1H″ illustrate example alternative nanowire cross-sectional geometries relative to the nanowire of FIG. 1H, in accordance with some embodiments.

FIG. 2 illustrates a computing system implemented with integrated circuit structures and/or transistor devices formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. For instance, fins or multilayer stacks as variously provided herein may be tapered in their cross-sectional profile, such that they are wider at the bottom proximate the substrate and narrower at the top. In short, the figures are provided merely to show example structures and methodology.

### DETAILED DESCRIPTION

Silicon germanium (SiGe) nanowires can be fabricated by first forming a stack of sacrificial silicon (Si) layers that alternate with non-sacrificial SiGe layers. When it comes time to remove the sacrificial Si layers and release the non-sacrificial SiGe layers (e.g., during processing of the channel region of a transistor), a selective wet etch is used to primarily (or only) remove the sacrificial Si layers, leaving the non-sacrificial SiGe layers to be used as nanowires in a nanowire-based transistor. The stack of alternating Si/SiGe layers are conventionally formed on a Si substrate, such that the material below the bottom-most sacrificial Si layer is also Si. Thus, as can be understood, conventional selective etch processes that are used to remove the sacrificial Si layers also remove a portion of the underlying Si material that is native to the substrate, in the sub-channel. Etching the Si sub-channel in the vertical direction can cause faceting (and even severe faceting), which may be undesirable as the faceting may adversely affect device performance, integrity, and reliability. In some cases, conventional selective etch processes may remove the entire sub-channel, leaving voids that may also adversely affect device performance, integrity, and reliability.

Thus, and in accordance with one or more embodiments of the present disclosure, techniques are provided for fabricating nanowire transistors using directional selective etching. Recall that nanowires (e.g., SiGe nanowires) can be formed by selectively wet etching sacrificial layers (e.g., Si layers) layers to remove them from a stack of layers including alternating sacrificial and non-sacrificial layers, using a given etchant. Generally, a selective wet etch employing a given etchant can be used to remove at least one “select material” while not removing other material exposed to the etch (or removing that other material at a relatively slower rate). The techniques described herein expand upon such selective etch processing by including a directional component, which is generally referred to herein as a “directional selective etch” for ease of reference. In some embodiments, a directional selective etch may include a selective etch that only (or primarily) removes the select material in a targeted direction. For instance, in some such embodiments, a directional selective etch may be used to selectively remove Si relative to SiGe and also have a directional component that only (or primarily) removes Si in a horizontal or lateral direction. Further, in some embodiments, a directional selective etch may include a selective etch that does not remove the select material in a targeted direction (or removes the select material in that targeted direction at a slower rate relative to removal of the select material in another direction). In such embodiments, the undesired direction may be referred to as a non-targeted direction. For instance, in some such embodiments, a directional selective etch may be used to selectively remove Si relative to SiGe, but not remove Si in a vertical direction (or remove Si in a vertical direction at a slower rate relative to another direction, such as a horizontal/lateral direction). In such an embodiment, the vertical direction is the non-targeted direction. Therefore, directional selective etching can be used, in some embodiments, to remove sacrificial Si layers (e.g., in a horizontal direction), without removing exposed sub-channel Si or removing that sub-channel Si at a lower rate relative to using a conventional selective etch process.

In some embodiments, the directional component of directional selective etches as described herein may be expressed using the Miller index representations of crystallographic planes. Miller indices are known in the art and they are used as a crystallography notation system for planes in crystal lattices. For instance, planes that exist in a horizontal direction (e.g., horizontal planes) include the crystallographic planes having Miller indices represented by {001}, as is known in the art. Note that the use of a Miller index of ‘{hkl}’ represents the set of all planes that are equivalent to (hkl) by the symmetry of the lattice, as is also known in the art.

Therefore, in embodiments where a directional selective etch is employed, and the directional component targets removal of the select vertical plane material in the horizontal (or lateral) direction, such a directional selective etch may be considered to target the removal of the select material in the (110) crystallographic plane (e.g., consume material and etch in the lateral <110> direction). Further, planes that exist in a horizontal plane or co-planar with the original substrate (e.g., horizontal planes) include the crystallographic planes having Miller indices represented by {001}, as is known in the art. Therefore, in embodiments where a directional selective etch is employed, and the directional component is targeted to not remove select material in the vertical direction, such a directional selective etch may be considered to not remove the select material in the (001) crystallographic plane (or remove the select material at a slower rate relative to the removal of the select material in other planes), such that the {001} crystallographic planes are non-targeted. Thus, in some embodiments, a directional selective etch may target the removal of select material (e.g., Si) in a horizontal direction (e.g., in {110} crystallographic planes), and also not remove the select material (or remove it at a relatively slower rate) in a vertical direction (e.g., in {001} crystallographic planes). Such a directional selective etch may be used to form SiGe nanowires by selectively etching sacrificial Si layers (e.g., in a horizontal direction) without adversely impacting the Si sub-channel region (e.g., by non-targeting of the vertical direction), as will be apparent in light of this disclosure.

Use of the techniques and structures provided herein may be detectable using tools such as: electron microscopy including scanning/transmission electron microscopy (SEMITEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate an integrated circuit (IC) including a transistor having a nanowire (or nanoribbon or gate-all-around (GAA)) channel region configuration, where a sub-channel region does not include faceting (or voids) as a result of the directional selective etch processing performed to form the nanowire(s) included in the channel region. In some embodiments, the techniques may be used to form a transistor including one or more SiGe (or Ge) nanowires, where the transistor is formed on a Si substrate. In some cases, the techniques may be detected based on the selective etch process being performed to form one or more nanowires in the channel region of a transistor. For instance, in some such cases, if the selective etch process includes a directional component (e.g., targets at least one direction and/or discriminates against at least one direction), then the selective etch process is using the techniques described herein. Such a situation may be determined based on the particular etchant being employed during the selective etch process, for example. For instance, one such directional selective etchant includes ammonium hydroxide, ammonium fluoride, carboxylic acid, and at least one of 1-propanol and water, to provide an example. However, a multitude of other suitable directional selective etchants will be apparent in light of this disclosure. Numerous configurations and variations will be apparent in light of this disclosure.

Methodology and Architecture

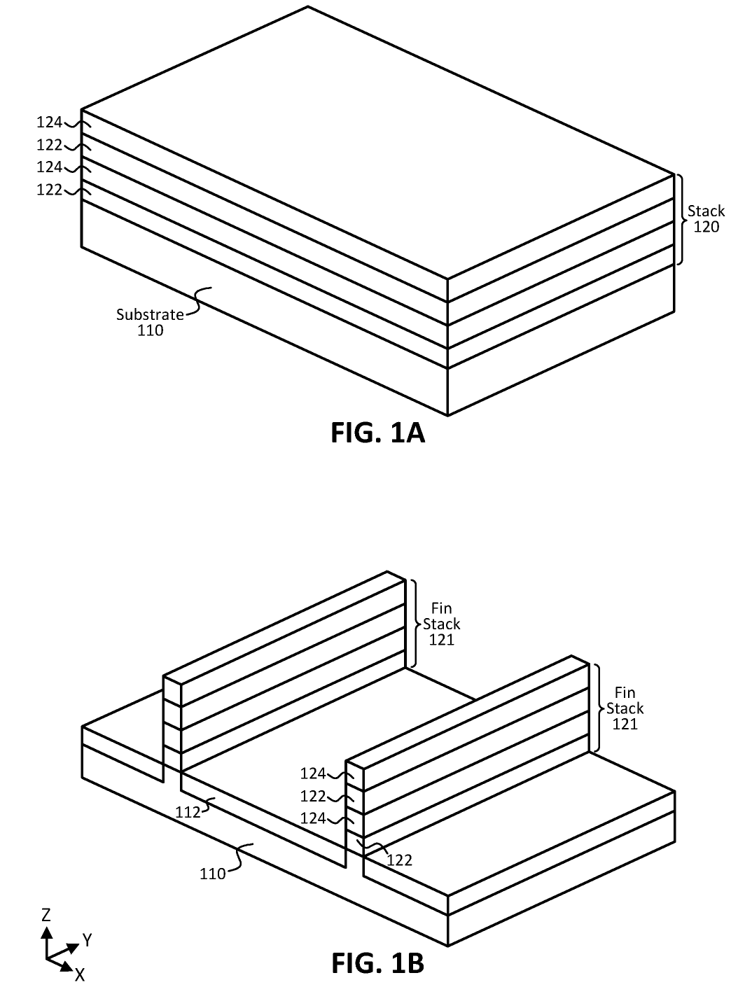

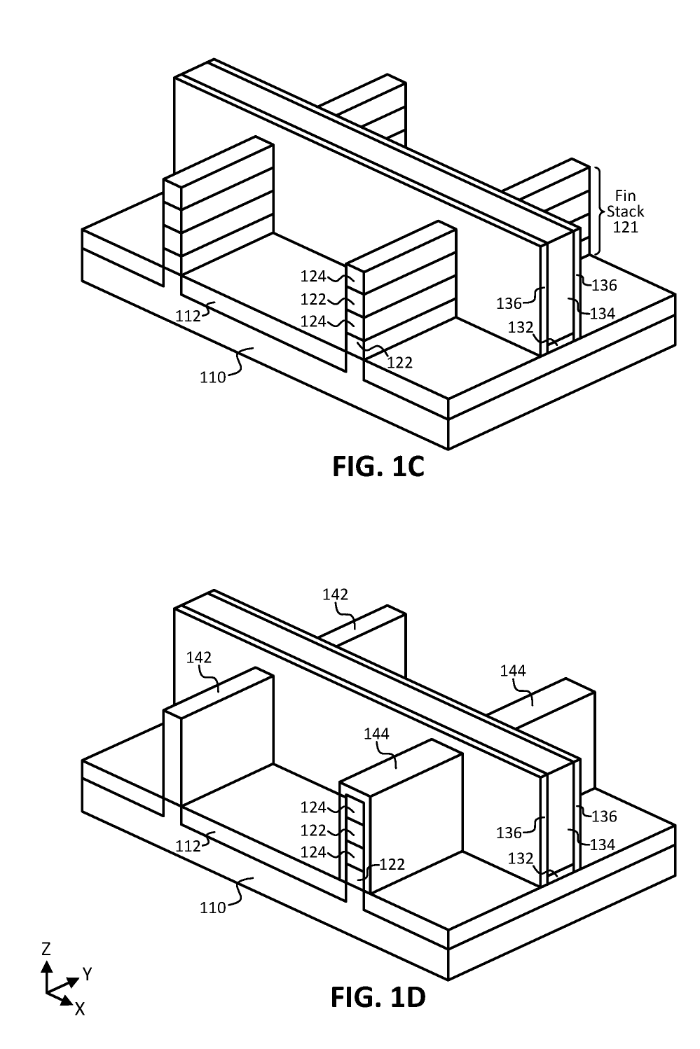

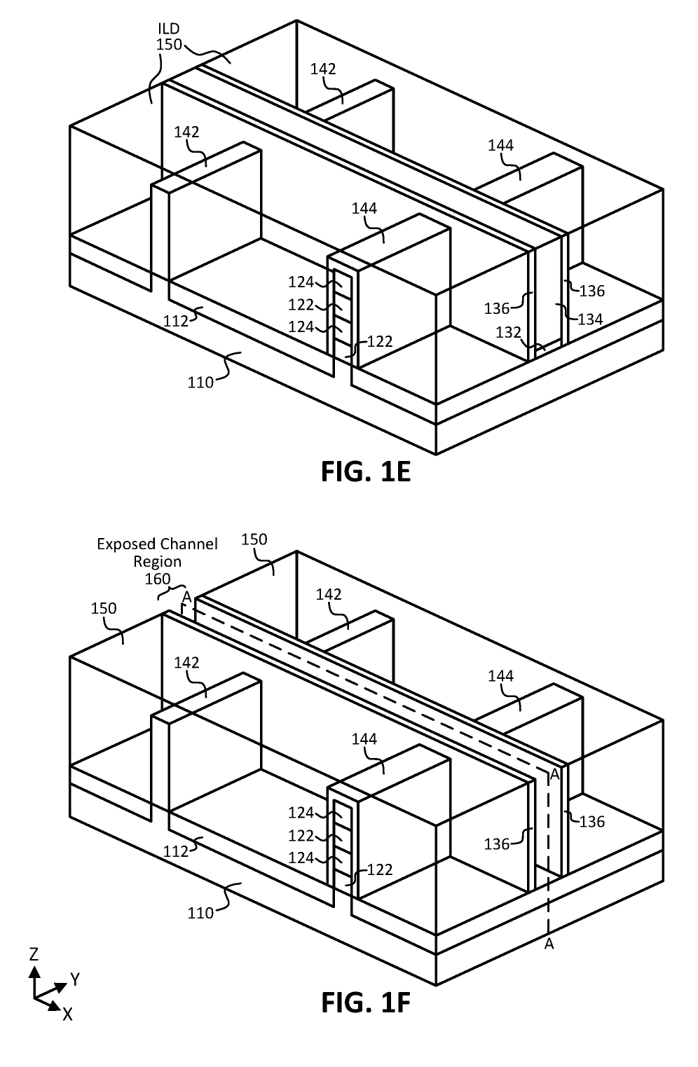

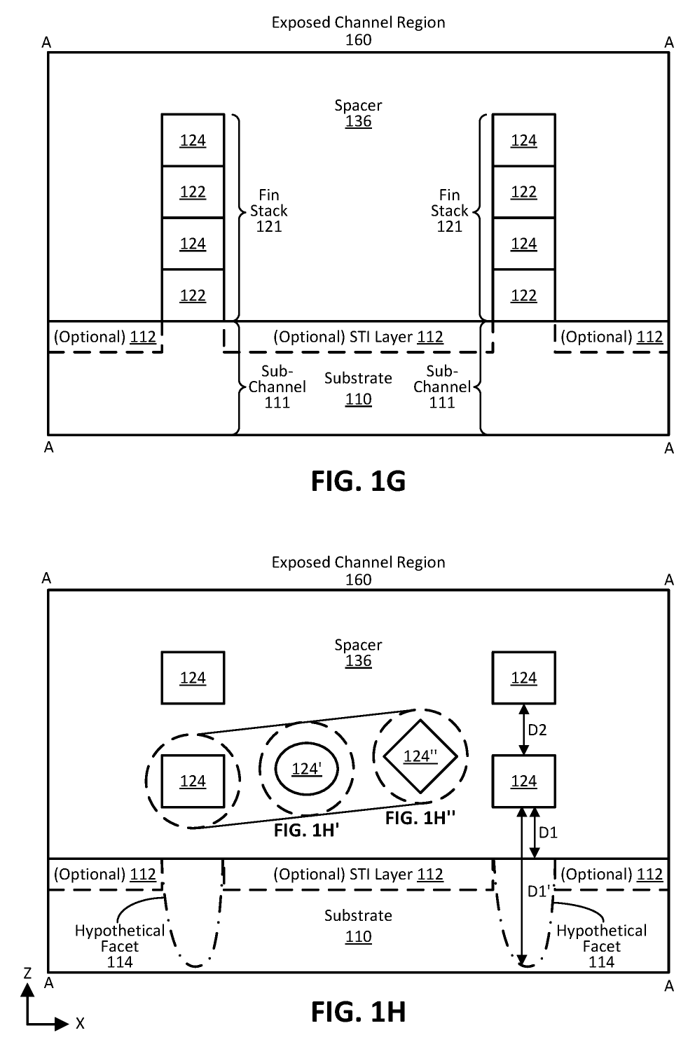

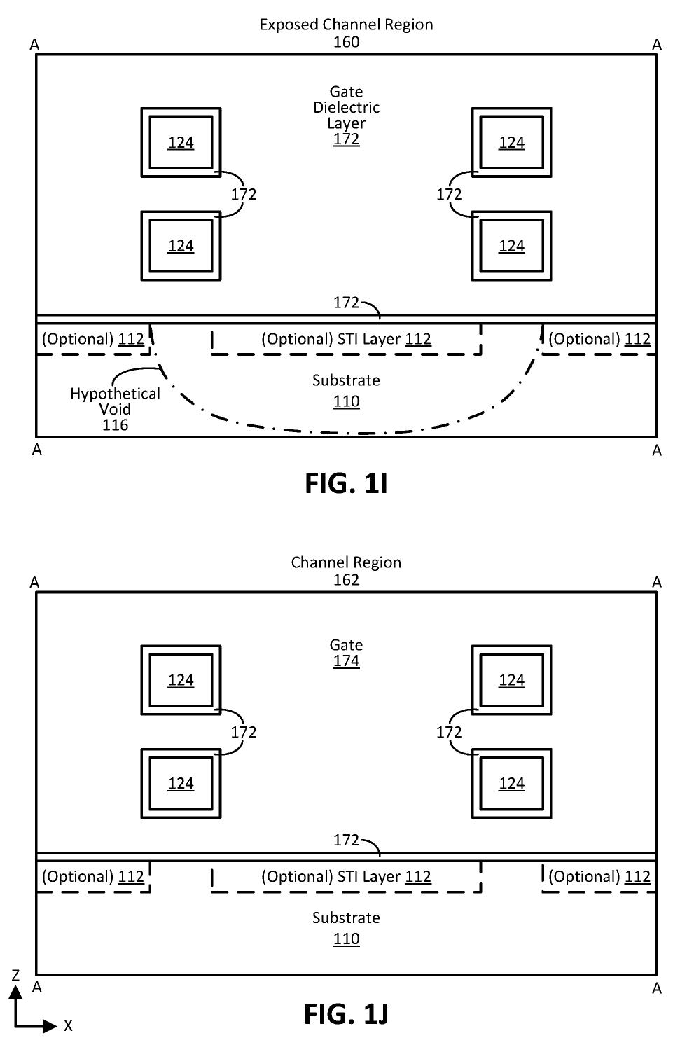

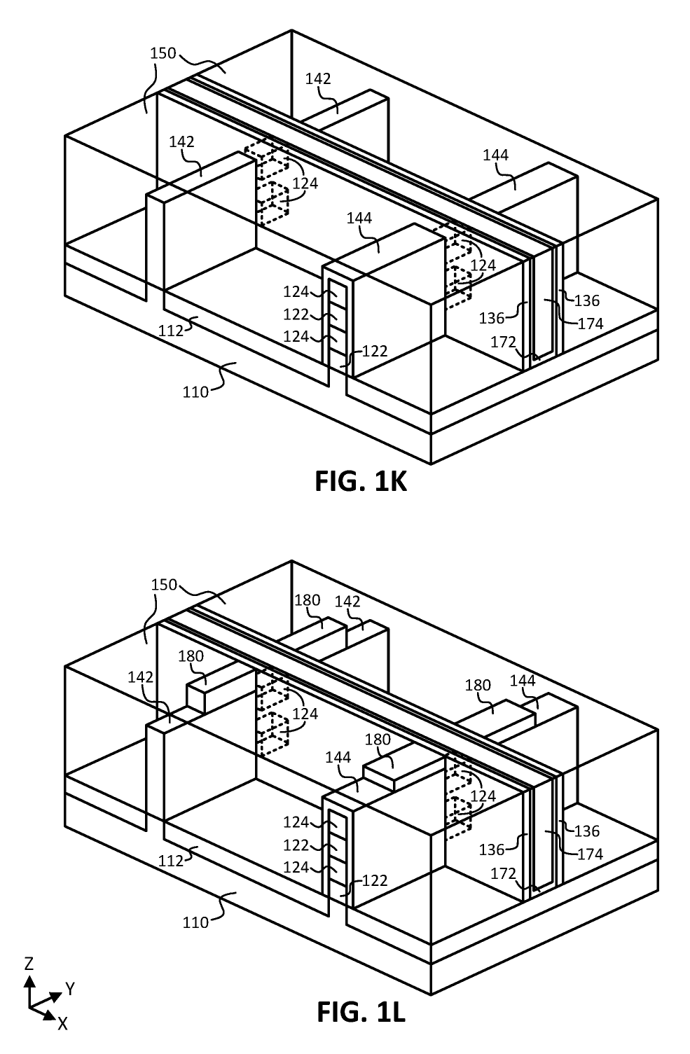

FIGS. 1A-L illustrate example integrated circuit (IC) structures resulting from a method configured to fabricate nanowire transistors using directional selective etching, in accordance with some embodiments of the present disclosure. The structures of FIGS. 1A-L are illustrated in the context of forming nanowire (or nanoribbon or gate-all-around (GAA)) transistors including two nanowires/nanoribbons, for ease of illustration. However, the techniques may be used to form nanowire transistors including any number of nanowires/nanoribbons, such as 1-10 or more, in accordance with some embodiments. As will be apparent in light of this disclosure, in some embodiments, the method includes forming a multilayer fin structure of alternating layers of sacrificial and non-sacrificial material (e.g., sacrificial Si and non-sacrificial SiGe), where the one or more non-sacrificial material layers are intended to be formed into nanowires/nanoribbons by removing the intervening sacrificial material layers via directional selective etch processing, in accordance with some embodiments. In some embodiments, the nanowires/nanoribbons may only be present in the channel region of the final transistor device, while in other embodiments, some or all of the nanowire/nanoribbon layers may also be present in one or both of the source/drain (S/D) regions, as will be apparent in light of this disclosure.

Various example transistor types that can benefit from the techniques described herein include, but are not limited to, field-effect transistors (FETs), metal-oxide-semiconductor FETs (MOSFETs), and tunnel-FETs (TFETs). In addition, the techniques can be used to benefit p-channel devices (e.g., p-MOS) and/or n-channel devices (e.g., n-MOS). However, in some embodiments, the techniques may be used to form SiGe nanowire transistor to be used for p-channel devices (e.g., p-MOS), as SiGe nanowires may be capable of providing performance benefits (e.g., increased mobility) relative to Si nanowires, for instance. Further, the techniques may be used to benefit various transistor-based devices, such as quantum devices (few to single electron) or complementary MOS (CMOS) devices/circuits, where either or both of the included p-type and n-type transistors may be formed using the techniques described herein (e.g., formed using directional selective etching), for example. In embodiments targeted for CMOS devices, the techniques may be only used for the p-channel transistor (e.g., p-MOS) portions of the CMOS device, in accordance with some such embodiments, as can be understood based on this disclosure. In some embodiments, the techniques may be used to benefit devices of varying scales, such as IC devices having critical dimensions in the micrometer (micron) range and/or in the nanometer (nm) range (e.g., formed at the 22, 14, 10, 7, 5, or 3 nm process nodes, or beyond).

FIG. 1A illustrates an example IC structure including substrate 110 with a stack 120 of alternating material layers 122/124 formed thereon, in accordance with an embodiment. In some embodiments, substrate 110 may include a bulk substrate including Si, a Si on insulator (SOI) structure where insulator material is an oxide material or dielectric material or some other electrically insulating material, or some other suitable multilayer structure where the top layer includes Si. In some embodiments, substrate 110 may generally include group IV semiconductor material, where “group IV semiconductor material” (or “group IV material” or generally, “IV”) as used herein includes at least one group IV element (e.g., silicon, germanium, carbon, tin, lead), such as Si, Ge, SiGe, and so forth. Note that group IV may also be known as the carbon group or IUPAC group 14, for example. In some embodiments, substrate 110 may include a surface crystalline orientation described by a Miller Index plane of {001}, {011}, or {111}, as will be apparent in light of this disclosure. Although substrate 110, in this example embodiment, is shown as having a thickness (dimension in the Z-axis direction) similar to layers 122 and 124 for ease of illustration, in some instances, substrate 110 may be much thicker than the other layers, such as having a thickness in the range of 50 to 950 microns, for example, which may be at least 100 times thicker than layers 122 and 124, or any other suitable thickness as will be apparent in light of this disclosure. However, in embodiments where substrate 110 is just the top layer of a multilayer substrate structure (and thus, substrate 110 is essentially a pseudo-substrate), that top layer need not be so thick and may be relatively thinner, such as having a thickness in the range of 20 nm to 10 microns, for example. In some cases, the original thickness of substrate 110 may be reduced as a result of processing in, on and/or above the substrate 110. In some embodiments, substrate 110 may be used for one or more other integrated circuit (IC) devices, such as various diodes (e.g., light-emitting diodes (LEDs) or laser diodes), various transistors (e.g., MOSFETs or TFETs), various capacitors (e.g., MOSCAPs), various microelectromechanical systems (MEMS), various nanoelectromechanical systems (NEMS), various radio frequency (RF) devices, various sensors, and/or any other suitable semiconductor or IC devices, depending on the end use or target application. Accordingly, in some embodiments, the transistor structures described herein may be included in a system-on-chip (SoC) application, as will be apparent in light of this disclosure.

In some embodiments, alternating layers 122 and 124 in multilayer stack 120 may be formed using any suitable techniques, such as depositing/growing the layers, one at a time, using molecular-beam epitaxy (MBE), chemical vapor deposition (CVD), atomic layer deposition (ALD), physical vapor deposition (PVD), and/or any other suitable process as will be apparent in light of this disclosure. Recall that multilayer stack 120 is intended to be later formed into nanowires for use in the channel region of one or more transistors, in this example embodiment. Further, in this example embodiment, layers 122 are intended to be sacrificial and layers 124 are intended to be formed into and used for the nanowires/nanoribbons, as will be apparent in light of this disclosure. Therefore, as shown in FIG. 1A, the bottom-most layer of stack 120 is sacrificial layer 122 and the top-most layer is non-sacrificial layer 124. However, the present disclosure is not intended to be so limited. For instance, stack 120 may alternatively have a first-formed/bottom-most layer of non-sacrificial material and/or a last-formed/top-most layer of sacrificial material, in accordance with some embodiments. In an embodiment employing the last-formed/top-most layer as sacrificial material, that sacrificial layer may be formed to protect the top-most non-sacrificial layer in the stack prior to directional selective etch processing used to form the nanowire(s) in the channel region, for example. In some embodiments, stack 120 may include more than two material layers, such as at least three different material layers, in any desired configuration to achieve a nanowire configuration for use in the channel region of a transistor, as can be understood based on this disclosure. In some such embodiments, the use of at least three different material layers may allow for different spacing between the final nanowires (e.g., via multiple selective etch processes) and/or allow for final nanowires of varying materials in the channel region, for example. As can be understood based on this disclosure, the desired number of nanowires may dictate the number of alternating sacrificial layer 122/non-sacrificial layer 124 sets initially formed (e.g., if 3 nanowires are desired, 3 sets of 122/124 layers may be initially formed, if 5 nanowires are desired, 5 sets of 122/124 layers may be initially formed, and so forth).

In some embodiments, sacrificial layers 122 and non-sacrificial layers 124 may have any suitable thicknesses (dimension in the Z-axis direction), such as thicknesses in the range of 1-100 nm (e.g., 2-10 nm), or any other suitable thickness as will be apparent in light of this disclosure. As can be understood based on this disclosure, the thicknesses of layers 122 and 124 will largely determine the final thicknesses of the one or more nanowires formed in the channel region of a transistor and the spaces therebetween (as well as the space between the bottom-most nanowire and substrate 100). Although layers 122 and 124 are all shown in the example embodiment of FIG. 1A as having the same thicknesses, the present disclosure is not intended to be so limited. For instance, in some embodiments, sacrificial layers 122 may all include similar thicknesses (e.g., plus/minus 1, 2, or 3 nm from their average thickness) and non-sacrificial layers 124 may all include similar thicknesses (e.g., plus/minus 1, 2, or 3 nm from their average thickness), but sacrificial layers 122 and non-sacrificial layers 124 may include different relative thicknesses, such that sacrificial layers 122 are thicker or thinner relative to non-sacrificial layers 124 (e.g., relatively at least 1, 2, 3, 4, 5, 6, 7, 8, 9, or 10 nm thicker or thinner, or some other suitable minimum threshold relative difference).

In some such embodiments, the thickness difference between the sacrificial layers 122 and non-sacrificial layers 124 may be employed to achieve a desired end configuration, including desired nanowire thicknesses and desired spacing distance between nanowires, for example. In some embodiments, sacrificial layers 122 and/or non-sacrificial layers 124 may include varying thicknesses, such that all sacrificial layers 122 need not include relatively similar thicknesses (e.g., two sacrificial layers 122 may have relative thickness differences of greater than 1, 2, 3, 4, or 5 nm) and/or all non-sacrificial layers 124 need not include relatively similar thicknesses (e.g., two non-sacrificial layers 124 may have relative thickness differences of greater than 1, 2, 3, 4, or 5 nm). For instance, in some such embodiments, the bottom-most sacrificial layer 122 may be relatively thicker than other sacrificial layers 122 in stack 120 (only one other sacrificial layer, in this example embodiment, but could be multiple other sacrificial layers in other embodiments), to provide an increased buffer between the bottom-most nanowire formed and substrate 110 after the sacrificial material is removed, for example. In some embodiments, the thickness of at least one layer in multilayer stack 120 may be selected such that the thickness of that at least one layer is below the critical thickness of the material of the at least one layer, to help prevent dislocations from forming. In some such embodiments, where the at least one layer may be grown pseudomorphically (below the critical thickness of the included material beyond which dislocations form), additional material schemes may be utilized, such as employing materials that are lattice mismatched, for example. In some embodiments, it may be desired to form dislocations in at least one layer of multilayer stack 120, such as in the sacrificial layers 122 (e.g., to assist with their subsequent removal during the directional selective etch processing in the channel region). Numerous different thickness schemes for the sacrificial and non-sacrificial layers in multilayer stack 120 will be apparent in light of this disclosure.

In some embodiments, sacrificial layers 122 and non-sacrificial layers 124 may include any suitable material, such as group IV semiconductor material, for example. For instance, in some embodiments, sacrificial layers 122 and non-sacrificial layers 124 may include at least one of Si and Ge, such that each layer includes at least either Si, Ge, or SiGe. In embodiments where SiGe material is included in one or more layers of stack 120, any Ge concentration may be used in the SiGe compound, such that the SiGe may be represented as Si₁₋ₓGeₓ where 0<x<1, for instance. In an example embodiment, sacrificial layers 122 include Si and non-sacrificial layers 124 include SiGe to form SiGe nanowires in the channel region of a transistor device. In some embodiments, all of sacrificial layers 122 may include similar material, such as each layer including Si, for example. In some embodiments, all of the non-sacrificial layers 124 may include similar material, such as each layer including SiGe, for example. In some embodiments, one or both of the sets of layers (sacrificial layers 122 and/or non-sacrificial layers 124) may include dissimilar material within layers in a single set. For instance, in some embodiments, non-sacrificial layers 124 may include dissimilar material in the set, such as one of the layers including SiGe and another including Ge, such that nanowires of varying materials in the same transistor can be employed, to provide an example. In some embodiments, the material of the layers in stack 120 (and/or the material of substrate 110) may be selected to facilitate directional selective etch processing, as will be apparent in light of this disclosure. In some embodiments, one or more of the layers in stack 120 may include other material to assist processing, such as including carbon (C) alloy to assist with making the non-sacrificial layers 124 more robust (e.g., more resistant to the directional selective etch processing) and/or including C alloy in the sacrificial layers 122 to provide additional etchant options for the directional selective etch processing, for example.

In some embodiments, one or more of the layers included in the multilayer stack 120 may include impurity dopants using any suitable doping scheme, such as doping one or more of the layers using suitable n-type dopants and/or doping one or more of the layers using suitable p-type dopants, for example. In some such embodiments, impurity dopants may be introduced via diffusion and/or ion implantation, for example, and/or via any other suitable techniques. However, in some embodiments, the layers in stack 120 need not include doping (e.g., neither of n-type or p-type dopants), such that the material in the layers are intrinsic or end up being only nominally undoped (e.g., with dopant concentrations of less than 1E18 atoms per cubic centimeter or some other maximum threshold dopant concentration). In some such embodiments, it may be desired that the layers in stack 120 (which includes layers to be in the final channel region of the transistor device) be intrinsic for use in a TFET device, as TFET devices generally include a source-channel-drain doping scheme of p-i-n or n-i-p, where ‘p’ stands for p-type doped material, ‘n’ stands for n-type material, and ‘i’ stands for intrinsic material. In some embodiments, one or more of the layers included in multilayer stack 120 (e.g., one or more of the sacrificial layers 122 and/or non-sacrificial layers 124) may include grading (e.g., increasing and/or decreasing) the content of one or more materials in the layer. Further, in some embodiments, one or more of the layers included in multilayer stack 120 may have a multilayer structure including at least two material layers, depending on the end use or target application. Further still, additional layers may be present in multilayer stack 120, such as one or more isolation layers (e.g., including dielectric/insulating material) that may be employed to help isolate portions of the final nanowire configuration, for example. Numerous different material and layer configurations for multilayer stack 120 will be apparent in light of this disclosure.

FIG. 1B illustrates an example resulting IC structure after the multilayer stack 120 in the structure of FIG. 1A is formed into one or more fins, in accordance with an embodiment. As shown in this example embodiment, stack 120 was formed into two fin-shaped stacks 121. In some embodiments, any suitable processing may be used to form fins stacks 121, such as patterning (using lithography and etching) stack 120 into the fin stacks 121 shown, for example. Such a patterning process may be similar to a shallow trench recess (STR) process that is employed to form finned (e.g., tri-gate or FinFET) transistors. Any number of lithography and etch processes may to pattern the fin stacks 121, in accordance with some embodiments. Although only two fin stacks 121 are shown in FIG. 1B for ease of illustration, the IC structure may include any number of fin stacks formed from multilayer stack 120, such as 1, 2, 3, 4, 5, 10, 25, 50, hundreds, thousands, millions, or more, as the devices to be formed can be on the nanotechnology scale, as can be understood based on this disclosure. As shown in FIG. 1B, the left and right fin stacks 121 include similar heights (dimension in the Z-axis direction) and widths (dimension in the X-axis direction). However, the present disclosure is not intended to be so limited. For instance, in some embodiments, the fin stacks 121 (when there are multiple fin stacks included) may be formed to have varying heights and/or varying widths. Note that although the fin stacks 121 are shown as generally having a rectangular shape with 90 degree angles, such a shape is used for ease of illustration and the present disclosure is not intended to be so limited.

As is also shown in FIG. 1B, the structure includes optional shallow trench isolation (STI) layer 112, which may be formed using any suitable techniques. For instance, STI layer 112, when present, may be formed by etching into substrate 110 to form fins of native material and depositing the STI layer 112 material as shown, in accordance with some embodiments. In other embodiments, STI layer 112 may be deposited between the fin stacks 121 and then recessed, and in some such embodiments, STI layer 112 may be level with at least a portion of the bottom sacrificial layer 122, for example, as opposed to being level with native portions of substrate 110, for instance. However, in some embodiments (e.g., embodiments where substrate 110 is an SOI substrate), STI layer 112 may be absent, as can be understood based on this disclosure.

In some embodiments, fin stacks 121 may be formed using other suitable processing. For instance, in an example embodiment, the fins may be formed by forming fins in substrate 110 (fins native to the substrate), forming STI material between the native fins, removing at least a portion of the native fins to form fin trenches, and depositing the multilayer stack in the fin trenches, and recessing (or removing) the STI material (e.g., to form fin stacks as shown in FIG. 1B). In such an example embodiment, STI material may be present between the fin stacks and such STI material may include any suitable dielectric, oxide (e.g., silicon dioxide), nitride (e.g., silicon nitride), and or other electrically insulating material, for example. Further, such an example embodiment may employ an aspect ratio trapping (ART) scheme, where the native fins are formed to have a particular height to width ratio (e.g., greater than 1.5, 2, 3, 4, 5, 10, or some other suitable ratio) such that when they are later removed or recessed, the resulting fin trenches formed allow for any defects that may otherwise be present in the replacement multilayer fin stack to terminate on a side surface (e.g., a surface of the STI material) as the material grows vertically. Regardless of the processing used to form fin stacks 121, in some embodiments, STI material may be present between two such fin stacks 121 to provide electrical isolation therebetween, for example. However, the embodiment shown in FIG. 1B does not include such STI material and thus, it need not be present in some embodiments.

FIG. 1C illustrates an example resulting IC structure after a dummy gate stack is formed on the structure of FIG. 1B, in accordance with an embodiment. In this example embodiment, dummy gate dielectric layer 132 and dummy gate 134 include sacrificial material (e.g., dummy poly-silicon for the gate 134) to be later removed and replaced in a replacement gate process. Such a gate last process flow is utilized in this example embodiment to allow for processing of the channel region into one or more nanowires when the channel region is exposed after removal of the dummy gate stack and prior to the formation of the final gate stack, as will be apparent in light of this disclosure. In some embodiments, formation of the dummy gate stack may be performed using any suitable techniques, such as depositing the dummy gate dielectric layer 132 and dummy gate (also referred to as dummy gate electrode) layer 134, patterning the dummy layers 132 and 134 into a dummy gate stack, depositing gate spacer material, and performing a spacer etch to form spacers 136 on either side of the dummy gate stack, shown in FIG. 1F, for example. Spacers 136 (also referred to as gate spacers or sidewall spacers) can help determine the channel length and can also help with replacement gate processes, for example. As can be understood based on this disclosure, the dummy gate stack (and spacers 136) helps to define the channel region and source/drain (S/D) regions of each fin stack 120, where the channel region is below the dummy gate stack (as it will be located below the final gate stack), and the S/D regions are adjacent to and on either side of the channel region. Spacers 136 may include any suitable material, such as any suitable electrical insulator, dielectric, oxide (e.g., silicon oxide), and/or nitride (e.g., silicon nitride) material, as will be apparent in light of this disclosure. In some embodiments, a hardmask may be formed on dummy gate 134 and/or on spacers 136, which may be included to protect those features during subsequent processing, for example.

FIG. 1D illustrates an example resulting IC structure after source/drain (S/D) processing has been performed on the structure of FIG. 1C, in accordance with an embodiment. In the example structure of FIG. 1D, different S/D regions have been formed to illustrate different S/D approaches that may be utilized. For instance, for the left-most fin stack 121, the material in the S/D regions was removed and replaced with replacement material 142, as shown. Note that the rectangular block shape of S/D regions 142 are used for ease of illustration; however, such regrown S/D regions may include other shapes and sizes, as can be understood based on this disclosure. The replacement S/D regions may be formed using any suitable techniques, such as removing at least a portion (or all) of the fin stack 121 and depositing/growing the replacement S/D regions 142. In some embodiments, STI material may be present, such that the replacement S/D material 142 may only grow from the exposed portion of substrate 110 or the remaining bottom portion of fin stack 121, for example. For the right-most fin stack 121, S/D material 144 was formed over the fin stack in the S/D regions, as shown. Such an overlying S/D feature 144 may be considered a cladding layer, for example. Thus, in such example S/D regions including layer 144, all or a portion of fin stack 121 may remain in the S/D regions, as can be understood based on this disclosure.

Regardless of the S/D scheme employed, the S/D regions may include any suitable material, such as group IV semiconductor material, for example. For instance, both features 142 and 144 may include Si, SiGe, and/or Ge, in accordance with some embodiments. Further, the S/D regions may include any suitable doping scheme, such that one or both of the S/D regions in a given S/D set may include suitable n-type and/or p-type impurity dopants, depending on the desired configuration. For instance, in the case of fabricating an n-MOS device, both of the S/D regions in a given set (e.g., both of 142 or 144) may include suitable n-type dopants, and in the case of fabricating a p-MOS device, both of the S/D regions in a given set may include suitable p-type dopants, in accordance with some embodiments. Recall that in TFET devices, the S/D regions in a given set are generally oppositely type doped, such that one of the S/D regions is n-type doped and the other is p-type doped. In some embodiments, one or both of the S/D regions in a given set may include a multilayer structure of two or more material layers, for example. In some embodiments, one or both of the S/D regions in a given set may include grading (e.g., increasing and/or decreasing) the content/concentration of one or more materials in at least a portion of the region(s). In some embodiments, additional layers may be included in the S/D regions, such as a cap layer used to reduce resistance reduction between the S/D regions and the S/D contacts, for example. Such a cap/resistance reducing layer may include different material than the main S/D material and/or include higher concentration of doping relative to the main S/D material, in accordance with some such embodiments. Note that in some embodiments, S/D processing may be performed after the final gate stack processing has been performed, such as after the processing performed to form the example structure of FIG. 1H, for example.

FIG. 1E illustrates an example resulting IC structure formed after a layer of interlayer dielectric (ILD) 150 material has been formed on the structure of FIG. 1D, in accordance with an embodiment. In some embodiments, ILD layer 150 may be formed using any suitable techniques, such as depositing the ILD material and optionally performing a polish/planarization process to form the example structure of FIG. 1E. Note that, in this example embodiment, ILD layer 150 is illustrated as transparent to allow for underlying features to be seen. In some embodiments, the ILD layer 150 may include a dielectric material, such as silicon dioxide or silicon nitride, or some other suitable electrically insulating material, for example.

FIG. 1F illustrates an example resulting IC structure formed after the dummy gate stack (including dummy gate dielectric layer 132 and dummy gate 134) of FIG. 1E has been removed to expose the channel region, in accordance with an embodiment. Note that the exposed channel region is indicated as 160 in the figures. In some embodiments, removing the dummy gate stack may include first removing a hardmask layer that is formed on the dummy gate stack (when such a hardmask layer is present), and then removing the dummy gate stack layers 134 and 132 (dummy gate 134 and dummy gate electrode 132, in this example case) using any suitable techniques, such as etches, polishes, and/or cleaning processes, for example. The A plane in FIG. 1F is used to indicate the cross-sectional views of FIGS. 1G-J, as will be described in more detail below.

FIGS. 1G-J illustrate cross-sectional views taken along plane A of FIG. 1F, showing example IC structures formed during channel region and gate stack processing, in accordance with some embodiments. As shown in FIG. 1G, the structure includes the same IC structure as that of FIG. 1F, except that a different view is used to assist in illustrating processing that occurs continuing from the structure of FIG. 1H. Therefore, as shown in FIG. 1G, the structure includes the two fin stacks 121 that were previously formed above and on substrate 110, with spacer 136 behind the fin stacks 121. To assist with the orientation between the structure of FIGS. 1F and 1G, one can refer to the X, Y, and Z-axes that are included for each view. Recall that in some embodiments, STI material may be present between and on the outside of the fin stacks 121 of FIG. 1G, which may help protect substrate 110. For instance, the optional STI layer 112 is shown in FIGS. 1G-1J in dashed lines to illustrate where such an STI layer 112 may be located, when present. Note that sub-channel regions 111 are indicated in FIG. 1G, where such regions are below fin stacks 121 as shown. In this example embodiment, the material of sub-channel regions 111 is native to substrate 110; however, the present disclosure is not intended to be so limited. In some cases, sub-channel regions 111 may be considered sub-fin regions or portions, as they are below fin stacks 121. However, they will primarily be referred to as sub-channel or sub-channel regions herein for ease of reference, as they are regions below the channel region in the transistor device, where that channel region is converted to nanowires and thus no longer includes a fin configuration, as will be apparent in light of this disclosure. In some embodiments, optional STI layer 112, when present, may only be located between sub-channel regions 111 in the cross-sectional view shown in FIG. 1G (which is the case in this example embodiment).

FIG. 1H illustrates an example resulting IC structure after directional selective etch processing has been performed on the structure of FIG. 1G to remove sacrificial layers 122, in accordance with an embodiment. Recall that the techniques described herein expand upon selective etch processing by including a directional component, which is generally referred to herein as a “directional selective etch” for ease of reference. In some embodiments, the directional selective etch processing may include one or more selective etches that remove the material of sacrificial layers 122 at a rate of at least 1.5, 2, 3, 4, 5, 10, 50, 100, or 1000 times faster relative to the removal of the material of non-sacrificial layers 124 for a given etchant. In some embodiments, the directional selective etch processing may not remove any material (or remove a negligible amount of material) from the non-sacrificial layers 124, for example. In some embodiments, a directional selective etch may include a selective etch that only (or primarily) removes the select material (e.g., material included in sacrificial layers 122) in a targeted direction. For instance, in some such embodiments, a directional selective etch may be used to selectively remove Si relative to SiGe (and/or Ge) and also have a directional component that only (or primarily) removes Si in a horizontal or lateral direction. Further, in some embodiments, a directional selective etch may include a selective etch that does not remove the select material (e.g., material included in sacrificial layers 122) in a targeted direction (or removes the select material in that targeted direction at a slower rate relative to removal of the select material in another direction). For instance, in some such embodiments, a directional selective etch may be used to selectively remove Si relative to SiGe (and/or Ge), but not remove Si in a vertical direction (or remove Si in a vertical direction at a slower rate relative to another direction, such as a horizontal/lateral direction). Therefore, directional selective etching can be used, in some embodiments, to remove sacrificial Si layers (e.g., in a horizontal direction), without removing exposed sub-channel Si or removing that sub-channel Si at a lower rate relative to using a conventional selective etch process.

Typical Si wafers used in industry are (001) plane with notch or flat aligned to [110] direction. For example, in such a typical wafer, using the structure of FIG. 1F, the X, Y, and Z coordinates are presented such that X and Y are variants of <110> directions and Z is oriented to the [001] direction. For substrates at different orientations, the planes would rotate accordingly, as can be understood based on this disclosure. In some embodiments, the directional component of directional selective etches as described herein may be expressed using the Miller index representations of crystallographic planes. Miller indices are known in the art and they are used as a crystallography notation system for planes in crystal lattices. For instance, planes that exist in a horizontal direction (e.g., horizontal planes) include the crystallographic planes having Miller indices represented by {001}, as is known in the art. Note that the use of a Miller index of ‘{hkl}’ represents the set of all planes that are equivalent to (hkl) by the symmetry of the lattice, as is also known in the art. Therefore, in embodiments where a directional selective etch is employed, and the directional component targets removal of the select vertical planes of material in the horizontal (or lateral) direction, such a directional selective etch may be considered to target the removal of the select material in the {110} crystallographic planes. Further, planes that exist in a horizontal direction (e.g., horizontal planes) include the crystallographic planes having Miller indices represented by {001}, as is known in the art. Therefore, in embodiments where a directional selective etch is employed, and the directional component is targeted to not remove select material in the vertical direction, such a directional selective etch may be considered to not remove the select material in the (001) crystallographic plane (or remove the select material at a slower rate relative to the removal of the select material in other planes). Thus, in some embodiments, a directional selective etch may target the removal of select material (e.g., Si) in a horizontal direction (e.g., in <110> crystallographic direction, i.e., removal of material in {110} planes), and also not remove the select material (or remove it at a relatively slower rate) in a vertical direction (e.g., in (001) crystallographic plane).

As can be understood based on this disclosure, a given etchant used in a directional selective etch may be selected based on the material included in sacrificial layers 122, the material included in non-sacrificial layers 124, the material included in sub-channel 111 (which may be native to substrate 110, as is the case in FIG. 1G), desired selectivity for the wet etch process, desired directionality for the wet etch process, and/or any other suitable factor as will be apparent in light of this disclosure. For instance, in embodiments employing sacrificial layers 122 including Si, non-sacrificial layers 124 including SiGe (or Ge), and sub-channel regions 111 including Si, an example directional selective etch may include a given etchant that selectively removes Si relative to SiGe (e.g., removes Si material at least 1.5-100 times faster relative to removal of SiGe material) and also removes Si in at least one targeted direction (e.g., horizontal or lateral direction) and/or does not remove Si/removes Si relatively slower in at least one non-targeted direction (e.g., vertical direction). For example, in some such embodiments, the directional selective etch may employ a given etchant that removes Si in a horizontal direction at least 1.5-100 times faster than the given etchant removes Si in a vertical direction, or some other suitable relative rate as will be apparent in light of this disclosure. As can be understood, such a directional selective etch may also have to be selective to other exposed material (e.g., ILD 150 material, spacer 136 material, and so forth), such that the other exposed material is not removed (or removed at a relatively slower rate) during the directional selective etch process, for instance.

To provide an example directional selective etch process, such a process may use an etchant including 5 percent ammonium hydroxide with 1 percent ammonium fluoride and 2 percent carboxylic acid in a 1:1 (e.g., 50 percent:50 percent) mixture of 1-propanol and water, may be used to selectively remove Si relative to SiGe (or Ge) and include a directional component such that Si is only (or primarily) removed in the horizontal direction (or in {110} crystallographic planes) and/or such that Si is not removed (or removed at a relatively slower rate) in the vertical direction (or in (001) crystallographic plane), in accordance with an embodiment. In some such embodiments, the given etchant may generally include ammonium hydroxide in the range of 1-20 percent, ammonium fluoride in the range of 1-10 percent, and carboxylic acid in the range of 1-10 percent, or any other suitable percentages as will be apparent in light of this disclosure. Further, in some such embodiments, the given etchant may include the 1-propanol and water mixture in any ratio, such as from pure 1-propanol to pure water, where the mixture may be represented as 1-propanol:water in percentages of 0-100%: 100-0%, for example. Numerous suitable directional selective etch processes and suitable etchants will be apparent in light of this disclosure.

Directional selective etchants can be contrasted with etchants used for conventional selective etch processes (e.g., ammonium hydroxide), where those conventional selective etchants do not include a directional component and thus do not target (and/or discriminate against) selective etching in any directions, as can be understood based on this disclosure. In addition, the detection of the use of directional selective etchants can be compared to etchants used for conventional selective etch processes, in accordance with some embodiments. For instance, in some cases, conventional selective etch processes using conventional selective etchants (e.g., ammonium hydroxide) may cause faceting in sub-channel (or sub-fin) regions 111, such as is shown in FIG. 1H with hypothetical example facets 114. In such cases, it can be understood that the material of the sub-channel regions 111 is removed by the conventional selective etchants, as they do not discriminate against removing material in a vertical direction and therefore etch downward into the sub-channel 111. For instance, as shown in FIG. 1H, distance D1 is the maximum distance between the bottom-most nanowire 124 and the underlying sub-channel (or sub-fin) region 111, where that distance (or a similar distance) can be achieved using directional selective etch processing, in accordance with some embodiments. However, using conventional selective etch processing results in faceting (e.g., hypothetical facet 114), where the distance between the bottom-most nanowire 124 and the underlying sub-channel (or sub-fin) region would be increased as a result of the faceting, such that D1′ is greater than D1, such as D1′ being greater than D1 by at least 1-30 nm (or a larger quantity) and/or the ratio of D1′ to D1 (D1′:D1) being greater than an amount in the range of 1.1-5 (or a larger amount), for example. In some embodiments, directional selective etch processing techniques may be detected through the lack of a facet in the sub-channel region (e.g., lack of hypothetical facet 114). In some embodiments, the non-present facet may be defined as being a dip or curve down from a horizontal plane (e.g., a crystallographic plane having a Miller index represented by (001)) tangent to the top of the sub-channel region of greater than an amount in the range of 1-50 nm (e.g., greater than an amount in the range of 2-20 nm), or greater than some other suitable threshold minimum amount as will be apparent in light of this disclosure. As can be understood, the dimension of that dip or curve down would be D1′ minus D1, in the example structure shown in FIG. 1H, for instance.

Further, in some cases, conventional selective etch processes using conventional selective etchants may etch out an entire sub-channel (or sub-fin) region 111 and/or etch into substrate 110 such that voids may be formed under the channel region, where an example hypothetical void 116 is shown in FIG. 1I, for instance. Such a void (e.g., void 116) may allow wet chemistry from subsequent cleaning processes to fill in the void and get trapped, where the wet chemistry may spontaneously pressurize under the high heats used in fabricating and operating the transistor device, which would be highly undesirable and could render the device unusable. Also, such a void (e.g., void 116) may cause one or more transistors to electrically short, which would also be highly undesirable and could also render the device unusable. Therefore, directional selective etching can overcome these issues by preventing (or greatly reducing) the removal of sub-channel (or sub-fin) material, as can be understood based on this disclosure. Note that hypothetical void 116 is shown in FIG. 1I instead of FIG. 1H for clarity of illustration. Also note that, in some embodiments, directional selective etching processing may also include one or more conventional selective etch processes. For instance, a conventional selective etch using ammonium hydroxide may be briefly performed after performing directional selective etch processing to assist with removing any remaining material from sacrificial layers 122 without adversely affecting the sub-channel region, to provide an example.

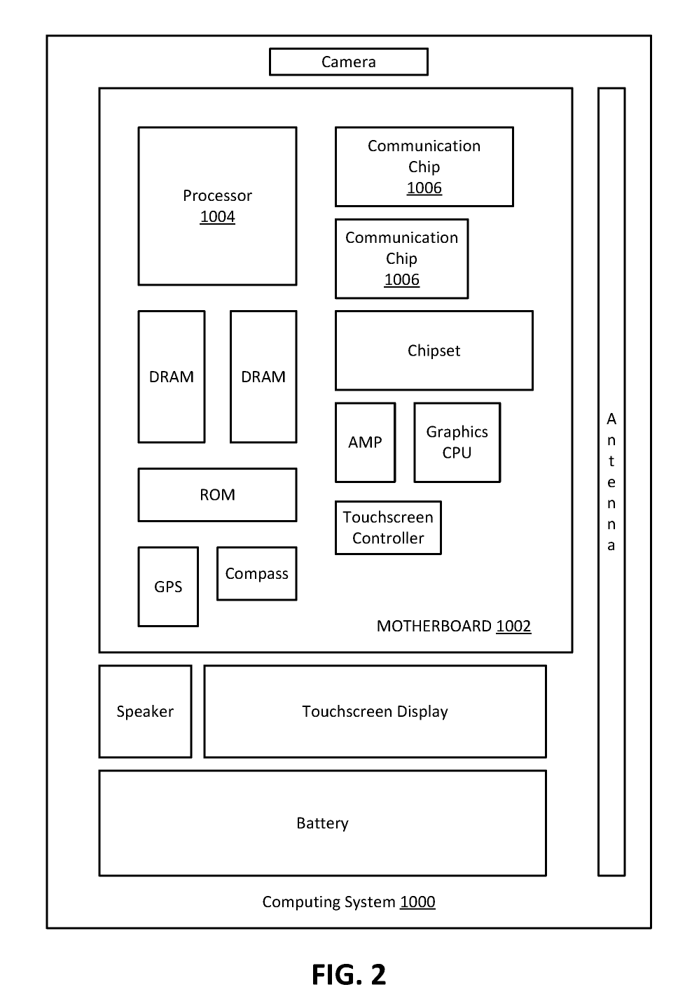

As can be understood based on FIGS. 1G-1H, the non-sacrificial layers 124 of FIG. 1G became the nanowires 124 of FIG. 1H after sacrificial layers 122 were removed via directional selective etch processing (only in the exposed channel region 160, as the remainder of the structure of FIG. 1F is covered with ILD layer 150). Thus, when non-sacrificial layers 124 are included in a multilayer fin stack 121, they are referred to as such herein, but once the non-sacrificial layers 124 are converted into nanowires via removal of overlying/underlying sacrificial layers 124, they will be referred to as nanowires 124. Recall that any number of nanowires/nanoribbons may be formed in the channel region of a GAA transistor, in accordance with some embodiments. Therefore, although only two nanowires 124 are formed in the exposed channel region 160 in the example structure of FIG. 1H, the directional selective etch processing may be used to form 1-10 or more nanowires, as desired. In some embodiments, the directional selective etch processing may not completely remove the sacrificial portion of the multilayer fin stack 121, such that at least a portion of one or more sacrificial layers 122 may still be present in the end structure, for example. Therefore, in some such embodiments, the directional selective etch processing may be considered to at least partially remove the sacrificial portion of the multilayer fin stack 121, for example. Also note that although the nanowires 124 are depicted as generally having a rectangular shape in the cross-sectional view of FIG. 1H, the present disclosure is not intended to be so limited. For example, in some embodiments, included nanowires may have different cross-sectional geometries, which may more-so resemble a circle, semi-circle, ellipse, semi-ellipse, oval, semi-oval, square, parallelogram, rhombus, trapezoid, diamond, triangle, pentagon, hexagon, and so forth, regardless of orientation. Further, two nanowires included in the same transistor channel region need not have similar cross-sectional geometry, in some embodiments. For instance, the blown out views of FIGS. 2H′ and 2H″ illustrate cross-sectional geometries that generally have an elliptical (nanowire 124′) and diamond shape (nanowire 124″), respectively.

In some embodiments, the nanowires 124 formed via the directional selective etch processing in the channel region 160 may retain their original thickness (dimension in the Z-axis direction). However, in other embodiments, some material may be removed from features 124 during the selective etch processing. Therefore, in some embodiments, the resulting nanowires 124 may include a maximum thickness (dimension in the Z-axis or vertical direction) in the range of 1-100 nm (e.g., 2-10 nm), or any other suitable maximum thickness as will be apparent in light of this disclosure. Further, in some embodiments, the nanowires within the channel region of a transistor (e.g., the set of nanowires 124 on the left side or the set on the right side, or both) may include nanowires of varying maximum thicknesses, such that two nanowires may have different relative thicknesses (e.g., relative maximum thickness difference of at least 1, 2, 3, 4, 5, or 10 nm). However, in other embodiments, the nanowires within the channel region of a transistor may include nanowires of similar maximum thicknesses, such that each nanowire is within 1, 2, or 3 nm of the average maximum thickness of all of the nanowires in the channel region, or within some other suitable amount as will be apparent in light of this disclosure.

The space/distance between nanowires included in a transistor channel region may also vary, in accordance with some embodiments. In some embodiments, the minimum distance between two nanowires in a channel region (e.g., the dimension indicated as distance D2 in FIG. 1H) may be in the range of 1-50 nm (e.g., 2-10 nm) or some other suitable amount as will be apparent in light of this disclosure. In some embodiments, the minimum distance between two nanowires may be less than a quantity in the range of 2-10 nm, or less than some other suitable maximum threshold amount as will be apparent in light of this disclosure. In some embodiments, the minimum distance (e.g., distance D2) that can be achieved between two nanowires formed using the techniques herein employing directional selective etching as variously described may be relatively smaller compared to techniques of forming similar nanowires with conventional selective etching. Therefore, as a result of being able to achieve smaller minimum distances (e.g., due to the lack of or reduced diffusion between sacrificial and non-sacrificial layers), more nanowires may be formed in a given channel region height, thereby leading to an improvement in transistor performance, for example. In some embodiments, the difference between distance D1 and D2 may be less than a quantity in the range of 1-10 nm, or less than some other suitable maximum threshold as will be apparent in light of this disclosure. Such a small difference may be achievable based on the use of directional selective etch processing, for example. For instance, the difference between D2 and D1′ may be relatively greater than the difference between D2 and D1, in accordance with some embodiments, as a result of using directional selective etch processing compared to using conventional selective etch processing. Numerous differences between structures employing directional selective etch techniques as described herein and structures employing conventional selective etch techniques will be apparent in light of this disclosure.

FIG. 1I illustrates an example resulting IC structure after gate dielectric layer 172 has been deposited in the exposed channel region 160 of the structure of FIG. 1H, in accordance with an embodiment. In some embodiments, gate dielectric layer 172 may be formed using any suitable techniques, such as using any suitable deposition process (e.g., MBE, CVD, ALD, PVD), for example. In some embodiments, gate dielectric layer 172 may include silicon dioxide and/or a high-k dielectric material, depending on the end use or target application. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 172 to improve its quality when a high-k material is used, for example. In some embodiments, gate dielectric layer 172 may be relatively thin, such as having a thickness in the range of 1-20 nm, for example, or some other suitable thickness as will be apparent in light of this disclosure. Note that gate dielectric layer 172 was formed on the bottom of the exposed channel region from the structure of FIG. 1H and also on the exposed sidewalls of spacers 136, as can be understood based on the structure of FIG. 1I.

FIG. 1J illustrates an example resulting IC structure after gate (or gate electrode) 174 has been deposited in the exposed channel region 160 of the structure of FIG. 1I, in accordance with an embodiment. In some embodiments, gate 174 may be formed using any suitable techniques, such as using any suitable deposition process (e.g., MBE, CVD, ALD, PVD), for example. In some embodiments, gate (or gate electrode) 174 may include a wide range of materials, such as polysilicon, silicon nitride, silicon carbide, or various suitable metals or metal alloys, such as aluminum (Al), tungsten (W), titanium (Ti), tantalum (Ta), copper (Cu), titanium nitride (TiN), or tantalum nitride (TaN), for example. In some embodiments, gate 174 may have a thickness in the range of 10-200 nm, for example, or some other suitable thickness as will be apparent in light of this disclosure. In some embodiments, gate dielectric layer 172 and/or gate 174 may include a multilayer structure of two or more material layers, for example. In some embodiments, gate dielectric layer 172 and/or gate 174 may include grading (e.g., increasing and/or decreasing) the content/concentration of one or more materials in at least a portion of the feature(s). Additional layers may be present in the final gate stack (e.g., in addition to gate dielectric layer 172 and gate 174), in some embodiments, such as one or more work function layers or other suitable layers, for example. As shown in the example embodiment of FIG. 1J, gate 174 (and the entire gate stack, in general) wraps completely or 100 percent around each nanowire 124. However, in some embodiments, the gate 174 may substantially wrap around each nanowire, such that it wraps around at least 75, 80, 85, 90, 95, or 98 percent of each nanowire, for example, or some other suitable amount as will be apparent in light of this disclosure. As can also be understood based on this disclosure, in some embodiments, gate dielectric layer 174 may wrap around more of one or more nanowires in the channel region compared to gate 172, due to, for example, gate dielectric layer 172 occupying the space between nanowires and/or preventing gate 174 from forming in the space between nanowires, particularly when that space (having a minimum dimension D, shown in FIG. 1H) is relatively small (e.g., less than 5 nm). Note that after gate stack processing has been performed and gate 174 has been formed, the exposed channel region 160 is no longer exposed and has become channel region 162 in FIG. 1J.

FIG. 1K illustrates a resulting example IC structure after the processing of FIGS. 1G-1J has been performed on the structure of FIG. 1F, in accordance with an embodiment. In other words, the structure of FIG. 1K is the same as the structure of FIG. 1J except that the view reverts back to the perspective view of the IC structure to illustrate subsequent processing, for example. Recall that the X, Y, and Z-axes are provided for all IC views to assist with orientation of the various figures. Also recall that in some embodiments, S/D processing may not occur until after the gate stack processing, such that S/D processing could be performed using the structure of FIG. 1K (if it had not yet been performed), for example.

FIG. 1L illustrates a resulting example IC structure after forming S/D contacts 180 for the structure of FIG. 1K, in accordance with an embodiment. In some embodiments, S/D contacts 180 may be formed using any suitable techniques, such as forming contact trenches in the ILD layer 150 over the respective S/D regions and depositing metal or metal alloy (or other suitable electrically conductive material) in the trenches. In some embodiments, S/D contact 180 formation may include silicidation, germinidation, and/or annealing processes, for example. In some embodiments, S/D contacts 180 may include aluminum or tungsten, although any suitable conductive metal or alloy can be used, such as silver, nickel-platinum, or nickel-aluminum, for example. In some embodiments, one or more of the S/D contacts 180 may include a resistance reducing metal and a contact plug metal, or just a contact plug, for instance. Example contact resistance reducing metals include, for instance, nickel, aluminum, titanium, gold, gold-germanium, nickel-platinum, or nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used. In some embodiments, additional layers may be present in the S/D contact regions, such as adhesion layers (e.g., titanium nitride) and/or liner or barrier layers (e.g., tantalum nitride), if so desired.

Additional processing to complete the IC after S/D contact processing may include back-end or back-end-of-line (BEOL) processing to form one or more metallization layers and/or to interconnect the transistor devices formed, for example. Any other suitable processing may be performed, as will be apparent in light of this disclosure. Note that the techniques and resulting IC structures formed therefrom are presented in a particular order for ease of description. However, one or more of the processes may be performed in a different order or may not be performed at all. Recall that the techniques may be used to form one or more transistor devices including any of the following: field-effect transistors (FETs), metal-oxide-semiconductor FETs (MOSFETs), tunnel-FETs (TFETs), and/or nanowire (or nanoribbon or gate-all-around (GAA)) configuration transistors (having any number of nanowires/nanoribbons). In addition, the devices formed may include p-type transistor devices (e.g., p-MOS) and/or n-type transistor devices (e.g., n-MOS). Further, the transistor-based devices may include complementary MOS (CMOS) devices or quantum devices (few to single electron), to name a few examples. Numerous variations and configurations will be apparent in light of this disclosure.

Example System

FIG. 2 illustrates a computing system 1000 implemented with integrated circuit structures and/or transistor devices formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1 is a method of forming an integrated circuit (IC), the method including: forming a multilayer fin-shaped stack in a channel region of a transistor, the multilayer fin-shaped stack including a first layer and a second layer below the first layer, the first layer including silicon germanium (SiGe) and the second layer including silicon (Si); and performing a wet etch including a given etchant, wherein the given etchant removes Si relatively faster than the given etchant removes SiGe, and wherein the given etchant removes Si relatively faster in a horizontal direction than the given etchant removes Si in a vertical direction.

Example 2 includes the subject matter of Example 1, wherein the horizontal direction includes vertical crystallographic planes having Miller indices represented by {110}.

Example 3 includes the subject matter of Example 1 or 2, wherein the vertical direction includes the horizontal crystallographic plane having a Miller index represented by (001).

Example 4 includes the subject matter of any of Examples 1-3, wherein the given etchant includes ammonium hydroxide, ammonium fluoride, carboxylic acid, and at least one of 1-propanol and water.

Example 5 includes the subject matter of any of Examples 1-4, wherein the given etchant includes ammonium hydroxide in the range of 1 to 20 percent.

Example 6 includes the subject matter of any of Examples 1-5, wherein the given etchant includes ammonium fluoride in the range of 1 to 10 percent.

Example 7 includes the subject matter of any of Examples 1-6, wherein the given etchant includes carboxylic acid in the range of 1 to 10 percent.

Example 8 includes the subject matter of any of Examples 1-7, wherein the given etchant includes a mixture of 1-propanol and water.

Example 9 includes the subject matter of any of Examples 1-8, wherein the given etchant removes Si in a horizontal direction a least five times faster than the given etchant removes Si in a vertical direction.

Example 10 includes the subject matter of any of Examples 1-9, wherein the given etchant only removes Si in a horizontal direction.

Example 11 includes the subject matter of any of Examples 1-10, wherein the given etchant does not remove Si material below the multilayer fin-shaped stack that is unable to be etched in a horizontal direction.

Example 12 includes the subject matter of any of Examples 1-11, wherein performing the wet etch forms a nanowire from the first layer.

Example 13 includes the subject matter of Example 12, further including forming a gate at least 75 percent around the nanowire.

Example 14 includes the subject matter of any of Examples 1-13, wherein performing the wet etch forms multiple nanowires.

Example 15 is an integrated circuit (IC) including: a substrate including silicon (Si); a transistor including a channel region above the substrate, the channel region including a nanowire, wherein the nanowire includes silicon germanium (SiGe), and a gate substantially around the nanowire; and a sub-channel region native to the substrate and below the channel region, wherein the sub-channel region does not include a facet.

Example 16 includes the subject matter of Example 15, wherein any dip or curve down included in the sub-channel region is less than 10 nanometers (nm) relative to a horizontal plane tangent to the top of the sub-channel region.

Example 17 includes the subject matter of Example 16, wherein any dip or curve down from the horizontal plane is less than 5 nm.

Example 18 includes the subject matter of any of Examples 15-17, wherein the nanowire includes n-type impurity dopants.

Example 19 includes the subject matter of any of Examples 15-18, wherein the nanowire has a maximum dimension in the vertical direction of less than 10 nanometers (nm).

Example 20 includes the subject matter of any of Examples 15-19, wherein substantially around the nanowire includes being at least 75 percent around the nanowire.

Example 21 includes the subject matter of any of Examples 15-20, further including a gate dielectric between the gate and the nanowire.

Example 22 includes the subject matter of any of Examples 15-21, wherein the channel region includes multiple nanowires and the gate is substantially around each nanowire.

Example 23 includes the subject matter of Example 22, wherein a first distance between a nanowire closest to the sub-channel region and the sub-channel region is less than 10 nanometers (nm) different than a second distance between two nanowires.

Example 24 includes the subject matter of any of Examples 15-23, further including insulator material on either side of the sub-channel region.

Example 25 includes the subject matter of any of Examples 15-24, wherein the substrate is a bulk wafer.

Example 26 includes the subject matter of any of Examples 15-24, wherein the substrate is a top layer of a multilayer structure.

Example 27 includes the subject matter of any of Examples 15-26, wherein the transistor is a p-channel metal-oxide-semiconductor field-effect transistor (p-MOS).

Example 28 is a complementary metal-oxide-semiconductor (CMOS) device including the subject matter of any of Examples 15-27.

Example 29 is a computing device including the subject matter of any of Examples 15-28.

Example 30 is an integrated circuit (IC) including: a substrate; a transistor including a channel region above the substrate, the channel region including a nanowire, wherein the nanowire includes at least one of silicon germanium (SiGe) and germanium (Ge), and a gate substantially around the nanowire; and a sub-channel region native to the substrate and below the channel region, wherein the sub-channel region does not include a facet.

Example 31 includes the subject matter of Example 30, wherein any dip or curve down included in the sub-channel region is less than 10 nanometers (nm) relative to a horizontal plane tangent to the top of the sub-channel region.

Example 32 includes the subject matter of Example 31, wherein any dip or curve down from the horizontal plane is less than 5 nm.

Example 33 includes the subject matter of any of Examples 30-32, wherein the nanowire includes n-type impurity dopants.

Example 34 includes the subject matter of any of Examples 30-33, wherein the nanowire has a maximum dimension in the vertical direction of less than 10 nanometers (nm).

Example 35 includes the subject matter of any of Examples 30-34, wherein substantially around the nanowire includes being at least 75 percent around the nanowire.

Example 36 includes the subject matter of any of Examples 30-35, further including a gate dielectric between the gate and the nanowire.

Example 37 includes the subject matter of any of Examples 30-36, wherein the channel region includes multiple nanowires and the gate is substantially around each nanowire.

Example 38 includes the subject matter of Example 37, wherein a first distance between a nanowire closest to the sub-channel region and the sub-channel region is less than 10 nanometers (nm) different than a second distance between two nanowires.

Example 39 includes the subject matter of any of Examples 30-38, further including insulator material on either side of the sub-channel region.

Example 40 includes the subject matter of any of Examples 30-39, wherein the substrate is a bulk wafer.

Example 41 includes the subject matter of any of Examples 30-39, wherein the substrate is a top layer of a multilayer structure.

Example 42 includes the subject matter of any of Examples 30-41, wherein the transistor is a p-channel metal-oxide-semiconductor field-effect transistor (p-MOS).

Example 43 is a complementary metal-oxide-semiconductor (CMOS) device including the subject matter of any of Examples 30-42.

Example 44 is a computing device including the subject matter of any of Examples 30-43.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. A method of forming an integrated circuit (IC), the method comprising:
forming a multilayer fin-shaped stack, the multilayer fin-shaped stack including a first layer and a second layer below the first layer, the first layer including silicon germanium (SiGe), and the second layer including silicon (Si) and being compositionally different from the first layer; and
performing a wet etch on a portion of the multilayer fin-shaped stack, the wet etch including a given etchant, wherein the given etchant removes Si relatively faster than the given etchant removes SiGe, and wherein the wet etch is directional in that it removes Si relatively faster in a horizontal direction than the given etchant removes Si in a vertical direction.

2. The method of claim 1, wherein
the horizontal direction includes vertical crystallographic planes having Miller indices represented by {110}; and/or
the vertical direction includes the horizontal crystallographic plane having a Miller index represented by (001).

3. (canceled)

4. The method of claim 1, wherein the given etchant includes ammonium hydroxide, ammonium fluoride, carboxylic acid, and at least one of 1-propanol and water.

5. The method of claim 1, wherein the given etchant includes ammonium hydroxide in the range of 1 to 20 percent.

6. The method of claim 1, wherein the given etchant includes ammonium fluoride in the range of 1 to 10 percent.

7. The method of claim 1, wherein the given etchant includes carboxylic acid in the range of 1 to 10 percent.

8. The method of claim 1, wherein the given etchant includes a mixture of 1-propanol and water.

9. The method of claim 1, wherein the given etchant removes Si in a horizontal direction a least five times faster than the given etchant removes Si in a vertical direction.

10. The method of claim 1, wherein the given etchant only removes Si in a horizontal direction.

11. The method of claim 1, wherein the given etchant does not remove Si material below the multilayer fin-shaped stack that is unable to be etched in a horizontal direction.

12. The method of claim 1, wherein performing the wet etch forms a nanowire from the first layer.

13. An integrated circuit (IC) comprising:
a substrate including silicon (Si);
a transistor including
a first semiconductor region above the substrate, the first semiconductor region including a nanowire, wherein the nanowire includes silicon and germanium (Ge), and
a gate substantially around the nanowire; and
a second semiconductor region native to the substrate and below the first semiconductor region, wherein the second semiconductor region does not include a facet.

14. The IC of claim 13, wherein any dip or curve downward included in the second semiconductor region is less than 10 nanometers (nm) relative to a horizontal plane tangent to the top of the second semiconductor region.

15. The IC of claim 14, wherein any dip or curve down from the horizontal plane is less than 5 nm.

16. (canceled)

17. The IC of claim 13, wherein the nanowire has a maximum dimension in the vertical direction of less than 10 nanometers (nm).

18. The IC of claim 13, wherein the first semiconductor region includes multiple nanowires and the gate is substantially around each nanowire.

19. The IC of claim 18, wherein a first distance between a nanowire closest to the second semiconductor region, and the second semiconductor region is less than 10 nanometers (nm) different than a second distance between two nanowires.

20. The IC of claim 13, further comprising insulator material on either side of the second semiconductor region.

21-23. (canceled)

24. An integrated circuit (IC) comprising:
a silicon substrate;
a transistor including
a first semiconductor region above the substrate, the first semiconductor region including a nanowire, wherein the nanowire includes germanium (Ge), and
a gate substantially around the nanowire; and
a second semiconductor region native to the substrate and below the first semiconductor region, wherein the second semiconductor region does not include a facet.

25. The IC of claim 24, wherein any dip or curve downward included in the second semiconductor region is less than 10 nanometers (nm) relative to a horizontal plane tangent to the top of the second semiconductor region.
